(19) United States
(12) Patent Application Publication
(10) Pub. No.: US 2026/0122934 A1
(43) Pub. Date: Apr. 30, 2026

(54) AlN SCHOTTKY BARRIER DIODES ON BULK AlN SUBSTRATES

(71) Applicants: Houqiang Fu, Chandler, AZ (US); Dinusha Herath Mudiyanselage, Mesa, AZ (US); Dawei Wang, Tempe, AZ (US)

(72) Inventors: Houqiang Fu, Chandler, AZ (US); Dinusha Herath Mudiyanselage, Mesa, AZ (US); Dawei Wang, Tempe, AZ (US)

(21) Appl. No.: 19/006,834

(22) Filed: Dec. 31, 2024

Related U.S. Application Data
(60) Provisional application No. 63/618,204, filed on Jan. 5, 2024.

(51) Int. Cl. H10D 8/60; H10D 8/01; H10D 62/85; H10D 64/62; H10D 64/64

(52) U.S. Cl. CPC H10D 8/60; H10D 8/051; H10D 62/8503; H10D 64/62; H10D 64/64

(57) ABSTRACT

A Schottky barrier diode includes an AlN substrate, an AlN layer formed by metalorganic chemical vapor deposition on the AlN substrate, a Si-doped n-AlN layer formed by metalorganic chemical vapor deposition on the AlN layer, a GaN capping layer, an Ohmic contact on the GaN capping layer, and a Schottky contact on the GaN capping layer, wherein a breakdown voltage of the Schottky barrier diode exceeds 3 kV. Fabricating a Schottky barrier diode includes depositing a first AlN layer on an AlN substrate, depositing a second AlN layer on the first AlN layer, depositing a capping layer on the second AlN layer, forming an Ohmic contact on the capping layer via electron beam deposition followed by rapid thermal annealing, and forming a Schottky contact on the capping layer by electron beam evaporation. The second AlN layer includes silicon-doped AlN, and the capping layer includes GaN.

### CROSS-REFERENCE TO RELATED APPLICATION

This application claims the benefit of U.S. Patent Application No. 63/618,204 filed on Jan. 5, 2024, which is incorporated herein by reference in its entirety.

### STATEMENT OF GOVERNMENT SUPPORT

This invention was made with government support under 2302696 awarded by the National Science Foundation and under DE-SC0021230 awarded by the Department of Energy. The government has certain rights in the invention.

### TECHNICAL FIELD

This invention relates to high breakdown voltage aluminum nitride (AlN) Schottky barrier diodes formed on bulk aluminum nitride (AlN) substrates by metalorganic chemical vapor deposition (MOCVD).

### BACKGROUND

Aluminum nitride (AlN) is an ultra-wide bandgap (UWBG) semiconductor that has a high breakdown field and superior thermal conductivity. While AlN Schottky barrier diodes (SBDs) having 1 kV breakdown voltages (BVs) have been demonstrated, multi-kV AlN Schottky barrier diodes are needed for high voltage high power devices.

### SUMMARY

This disclosure describes aluminum nitride (AlN) Schottky barrier diodes on bulk AlN substrates fabricated by metalorganic chemical vapor phase deposition (MOCVD), with breakdown voltages exceeding 3 kV.

The devices exhibit good rectifying characteristics with ON/OFF ratios on the order of 10⁶ to 10⁸ and excellent thermal stability from 298 K to 623 K. The device Schottky barrier height increases from 0.89 to 1.85 eV, and the ideality factor decreases from 4.29 to 1.95 with increasing temperature, which is ascribed to the inhomogeneous metal/AlN interface. At reverse bias of −3 kV, the devices show a low leakage current of 200 nA without the incorporation of any field plate structures or passivation techniques.

In a first general aspect, a Schottky barrier diode includes an AlN substrate, an AlN layer formed by metalorganic chemical vapor deposition on the AlN substrate, a Si-doped n-AlN layer formed by metalorganic chemical vapor deposition on the AlN layer, a GaN capping layer, an Ohmic contact on the GaN capping layer, and a Schottky contact on the GaN capping layer, wherein a breakdown voltage of the Schottky barrier diode exceeds 3 kV.

Implementations of the first general aspect may include one or more of the following features. In some cases, the AlN substrate includes (0001) bulk AlN. The AlN substrate can be formed by physical vapor transport. In some cases, a thickness of the AlN layer is about 1 μm. In some implementations, a thickness of the Si-doped n-AlN layer is about 200 nm. In some cases, the Si doping concentration in the n-AlN layer is about 1×10¹⁹ cm⁻³. A thickness of the GaN capping layer can be about 2 nm.

In some cases, the Ohmic contact includes a Ti/Al/Ni/Au stack. In some implementations, the Schottky contact includes a Pt/Au stack. In some cases, Ohmic contact has a cylindrical cross section and surrounds the Schottky contact. In some implementations, the Schottky contact has a circular cross section. A distance between an outer diameter of the Schottky contact and an inner diameter of the Ohmic contact can be in a range of about 50 μm to about 350 μm. In some cases, a thickness of the Ohmic contact and the Schottky contact is about 100 μm. In some implementations, the diode has an ON/OFF ratio in a range of about 10⁶ to 10⁸. The diode can be thermally stable from 298 K to 623 K. In some implementations, the Schottky barrier height increases from 0.89 eV to 1.85 CV and the ideality factor decreases from 4.29 to 1.95 with increasing temperature. At reverse bias of −3 kV, the diode can have a leakage current of 200 nA. In some cases, diode is free of field plate structures. In some implementations, the diode is free of passivation structures. In some cases, the diode is free of edge termination structures. In some implementations, the AlN layer is unintentionally doped. In some cases, the GaN capping layer is unintentionally doped.

In a second general aspect, fabricating a Schottky barrier diode includes a method of depositing a first AlN layer on an AlN substrate, wherein the first AlN layer includes AlN; depositing a second AlN layer on the first AlN layer, wherein the second AlN layer includes silicon-doped AlN; depositing a capping layer on the second AlN layer, wherein the capping layer includes GaN; forming an Ohmic contact on the capping layer via electron beam deposition followed by rapid thermal annealing; and forming a Schottky contact on the capping layer by electron beam evaporation.

The details of one or more embodiments of the subject matter of this disclosure are set forth in the accompanying drawings and the description. Other features, aspects, and advantages of the subject matter will become apparent from the description, the drawings, and the claims.

### BRIEF DESCRIPTION OF DRAWINGS

FIG. 1A shows a schematic of a cross-section of a fabricated aluminum nitride (AlN) Schottky barrier diodes (SBDs) on bulk AlN by metalorganic chemical vapor deposition (MOCVD) with Ti/Al/Ni/Au Ohmic contact and Pt/Au Schottky contact. FIG. 1B shows a top view of the device in FIG. 1A.

FIG. 2A shows a rocking curve of the (0002) peak of AlN epilayer by high-resolution X-ray diffraction. FIG. 2B shows a rocking curve of the (101̅2) peak of AlN epilayer by high-resolution X-ray diffraction.

FIG. 3A shows forward I-V characteristics of the AlN SBDs with different contact distances on a log scale. The inset shows an optical image of fabricated AlN device. FIG. 3B shows a temperature-dependent forward I-V characteristic of the AlN SBDs with a contact distance of 50 μm.

FIG. 4A shows an ideality factor and Schottky barrier height of the AlN SBDs as a function of temperature. FIG. 4B shows a relationship between Schottky barrier height and ideality factor.

FIG. 5A shows a C-V plot and 1/C²-V plot at room temperature for the AlN SBDs.

FIG. 5B shows a relationship between carrier concertation and temperature. Inset shows a temperature-dependent C-V measurement of the devices.

FIG. 6 shows reverse leakage of AlN SBDs.

### DETAILED DESCRIPTION

This disclosure describes lateral aluminum nitride (AlN) Schottky barrier diodes (SBDs) grown and fabricated on bulk AlN substrates by metalorganic chemical vapor deposition (MOCVD). The devices have a breakdown voltage that exceeds 3 kV and demonstrate excellent rectifying behaviors with ON/OFF ratios of 10⁶-10⁸ from 298 to 623 K and good thermal stability. With increasing temperature, φ_{b} increases from 0.89 to 1.85 eV, while n decreases from 4.29 to 1.95. At −3 kV, the devices exhibit a low leakage current of 200 nA without any field plate structure or passivation.

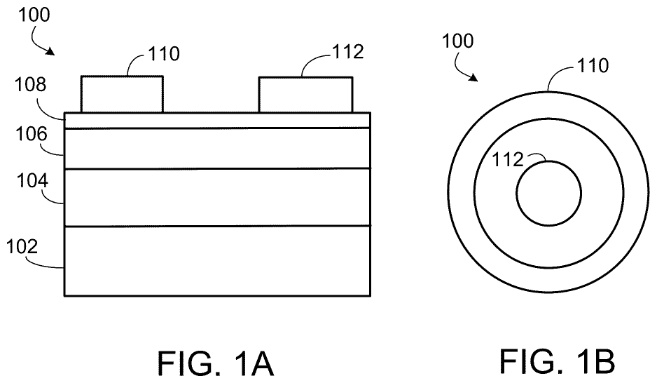

FIG. 1A depicts a device structure of a Schottky barrier diode 100. Schottky barrier diode 100 includes substrate 102, doped AlN layer 104, Si-doped AlN layer 106, gallium nitride (GaN) layer 108, Ohmic contact 110, and Schottky contact 112.

Suitable materials for substrate 102 include AlN. In one example, substrate 102 is a physical vapor transport (PVT) grown bulk AlN substrate. A thickness of substrate 102 is typically in a range of 0.5 mm to 0.6 mm. In one example, a thickness of substrate 102 is 0.53 mm.

In one example, doped AlN layer 104 is an unintentionally doped (UID) AlN layer. A thickness of doped AlN layer 104 is typically in a range of 0.5 μm to 1 μm. In one example, a thickness of doped AlN layer 104 is 1 μm.

In one example, Si-doped AlN layer 106 is a Si-doped n-AlN layer. A suitable dopant includes silane. A thickness of Si-doped AlN layer 106 is typically in a range of 200 nm to 500 nm. In one example, a thickness of Si-doped AlN layer 106 is 200 nm. A Si doping concentration of Si-doped AlN layer 106 is typically in a range of 1×10¹⁹ cm⁻³ to 2×10¹⁹ cm⁻³. In one example, a Si doping concentration of Si-doped AlN layer 106 is 1×10¹⁹ cm⁻³.

In one example, GaN layer 108 is an UID GaN capping layer. A thickness of GaN layer 108 is typically in a range of 2 nm to 5 nm. In one example, a thickness of GaN layer 108 is 2 nm.

FIG. 1B is a top view of Schottky barrier diode 100 showing Ohmic contact 110 and Schottky contact 112. In one example, Ohmic contact 110 is a Ti/Al/Ni/Au metal stack. A thickness of Ti in Ohmic contact 110 is typically in a range of 150 nm to 250 nm. A thickness of Al in Ohmic contact 110 is typically in a range of 80 nm to 120 nm. A thickness of Ni in Ohmic contact 110 is typically in a range of 25 nm to 50 nm. A thickness of Au in Ohmic contact 110 is typically in a range of 50 nm to 100 nm. In one example, a Ti/Al/Ni/Au metal stack had thicknesses of 25/100/25/50 nm. In one example, Ohmic contact 110 has a cylindrical cross section. Ohmic contact 110 typically has a width or diameter in a range of 75 μm to 125 μm. In one example, Ohmic contact 110 has a width or diameter of 100 μm.

In one example, Schottky contact 112 is a Pt/Au metal stack. A thickness of Pt in Schottky contact 112 is typically in a range of 15 nm to 35 nm. A thickness of Au in Schottky contact 112 is typically in a range of 75 nm to 150 nm. In one example, a thickness of the Pt/Au metal stack is 150 nm (e.g., 30/120 nm). In one example, Schottky contact 112 has a circular cross section. The distance between an outer diameter of Schottky contact 112 and an inner diameter of Ohmic contact 110 is typically in a range of about 50 μm to about 350 μm.

AlN epilayers are grown using MOCVD on bulk PVT AlN substrates. The as-grown sample undergoes a cleaning process, and is typically immersed in an acid solution with an acid: H₂O volume ratio in a range of 1:1 to 1:3 (e.g., 1:2). In one example, hydrochloric acid is used. The fabrication of AlN SBDs can be performed using optical photolithography and lift-off processes. Ohmic contacts are typically formed using Ti/Al/Ni/Au metal stacks deposited via electron beam deposition, followed by rapid thermal annealing (RTA) at a temperature in a range of 900° C. to 1100° C. In one example, RTA is performed at 1000° C. in N₂ for about 1 minute. Schottky contacts can be formed using Pt/Au metal stacks deposited via electron beam evaporation.

### Examples

Aluminum nitride (AlN) epilayers were grown using metalorganic chemical vapor deposition (MOCVD) on (0001) bulk physical vapor transport (PVT) AlN substrates. Trimethylaluminum (TMAI) and ammonia (NH₃) were used as the Al and N sources respectively, whereas N₂ diluted silane (SiH₄) was used as the n-type dopant Si. The device structure includes a 1-μm-thick unintentionally doped (UID) AlN layer as a resistive buffer, a 200 nm highly Si-doped n-AlN layer, and a 2 nm UID gallium nitride (GaN) capping layer. The GaN capping layer was used to prevent oxidation of the underlying AlN epilayers upon exposure to air, which could degrade device performance. The Si doping concentration in the n-AlN layer was 1×10¹⁹ cm⁻³.

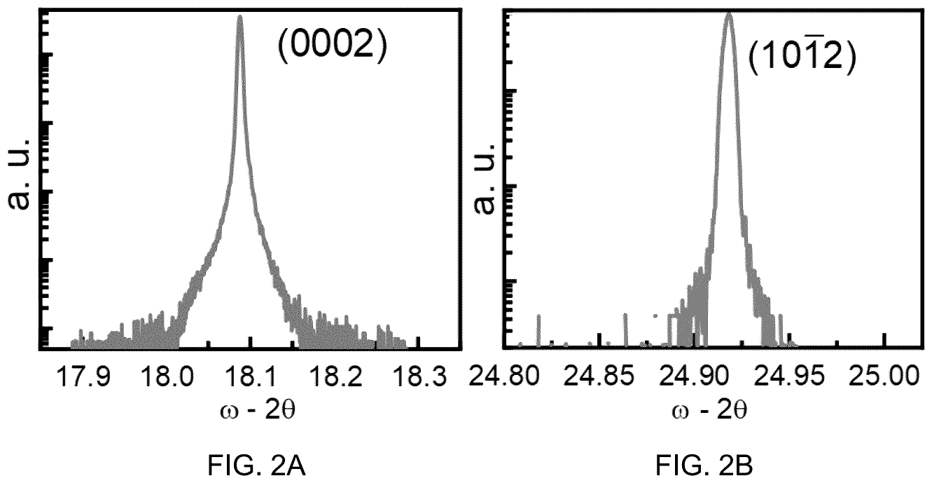

To assess the crystal quality of the MOCVD-grown AlN sample, high-resolution X-ray diffraction (HRXRD) measurements were conducted using the Rigaku SmartLab X-ray diffractometer system. FIGS. 2A and 2B depict the (0002) symmetric and (101̅2) asymmetric rocking curves (RCs) for the AlN sample, with a full-width half maximum (FWHM) of 17.6 arcsec for (0002) and 19.08 arcsec for (101̅2). The dislocation density was estimated to be in the range of 10⁴-10⁵ cm⁻². Furthermore, the surface morphology of the AlN sample was assessed using Bruker's Dimension atomic force microscopy (AFM), revealing a root-mean-square (RMS) roughness of ˜1.2 nm over a 2×2 μm² scanning area. These HRXRD and AFM results indicate that the MOCVD-grown AlN epilayers possessed a low dislocation density and a smooth surface. The as-grown sample underwent a cleaning process involving acetone, isopropyl alcohol, and deionized water aided by ultrasonication. Subsequently, it was immersed in a hydrochloric acid (HCl) solution with a 1:2 (HCl:H₂O) volume ratio.

The fabrication of AlN SBDs was performed using a well-known optical photolithography and lift-off processes. Ohmic contacts were formed using Ti/Al/Ni/Au (25/100/25/50 nm) metal stacks deposited via electron beam deposition, followed by rapid thermal annealing (RTA) at 1000° C. in N₂ for 1 minute. The circular Ohmic contact had a width of 100 μm. For Schottky contacts, Pt/Au (30/120 nm) metal stacks were deposited via electron beam evaporation. The distance between the anode and cathode contacts d, was varied between 50-350 μm. No field plate, passivation, or edge termination structures were implemented on the devices. Electrical measurements were performed on a probe station equipped with a Keithly 4200 SCS semiconductor analyzer and a thermal chuck. Reverse I-V characteristics were measured using Keysight B1505A Power Device Analyzer/Curve Tracer, and reverse breakdown measurements were conducted in insulating Fluorinert liquid FC-70 at room temperature.

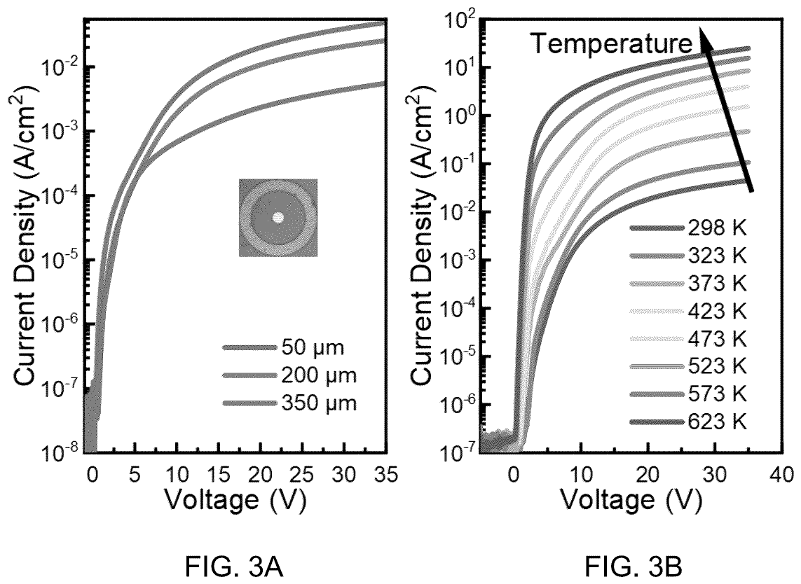

FIG. 3A shows the forward I-V characteristics of the AlN SBDs show ON/OFF ratios on the order of 10⁵-10⁶ and turn-on voltage of ˜2.5 V. The general diode equation for an SBD can be written as

$$J = {J}_{s} [ exp ( \frac{\text{?}}{nkT} ) - 1 ] \qquad ( 1 )$$

$${J}_{s} = A \text{?} {T}^{2} exp ( - \frac{q φ \text{?}}{kT} ) \qquad ( 2 )$$

$$\text{?} \text{indicates text missing or illegible when filed}$$

where J is the current density, Jₛ is the saturation current density, A* is the Richardson constant, Tis the temperature in Kelvin, q is the electron charge, φ_{b} is the Schottky barrier height, n is the ideality factor, k is the Boltzmann constant, m* is the effective electron mass, and h is the Planck constant. The Richardson constant used in the calculation was 57.7 Acm⁻²K⁻² using the effective electron mass of 0.48 m₀ where m₀ is the free electron mass. Based on Eqs. (1), and (2), similar Schottky barrier height (φ_{b}) of ˜0.9 eV was obtained for the devices with contact distances of 50, 200, and 350 μm. However, the ideality factor (n)varied with increasing distance between Ohmic and Schottky contacts. The minimum value of 4.29 was obtained for the devices with d=50 μm. However, other devices with larger contact distances exhibited a slightly larger n (6.11 and 7.52 for d=200 and 350 μm devices, respectively). This indicates that the current transport mechanism is likely to be influenced by surface states and/or resistance of the AlN epilayers due at least in part to relatively low carrier concentration. FIG. 3B shows the I-V curves of AlN SBDs at different temperatures show good temperature stability from 298 up to 623 K, and the device ON/OFF ratio increased from 10⁶ to 10⁸ as more carriers contribute to the current transport at higher temperatures.

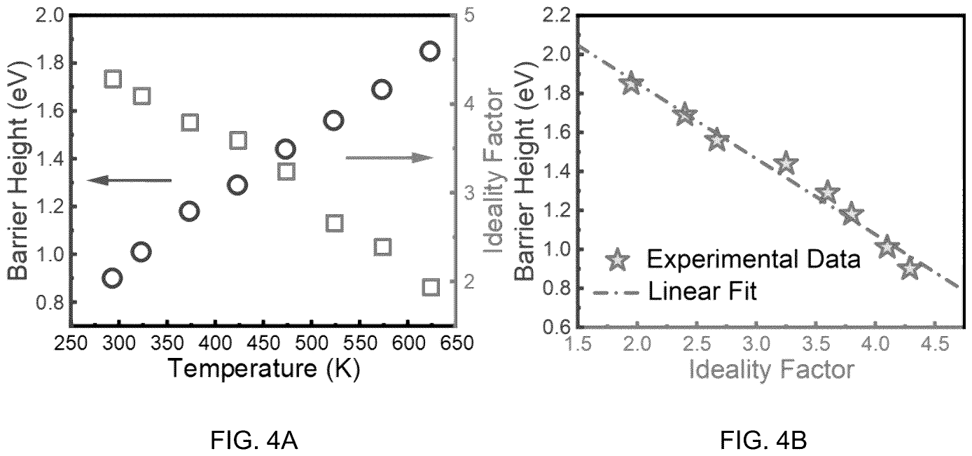

FIG. 4A shows the temperature-dependent φ_{b} and n of the AlN SBD (d=50 μm). The Pb increased from 0.89 to 1.85 eV, and n decreased from 4.29 to 1.95 with increasing temperature. FIG. 4B shows a linear relationship between φ_{b} and n of the devices. This can be ascribed as an inhomogeneous metal/AlN interface with distributed low and high Schottky barrier regions. As temperature increases, electrons can overcome higher Schottky barrier regions, leading to an increase in φ_{b}. In addition, the devices exhibited behaviors that are more closely aligned with the thermionic emission (TE) model with increasing temperature, as evidenced by the decreasing n.

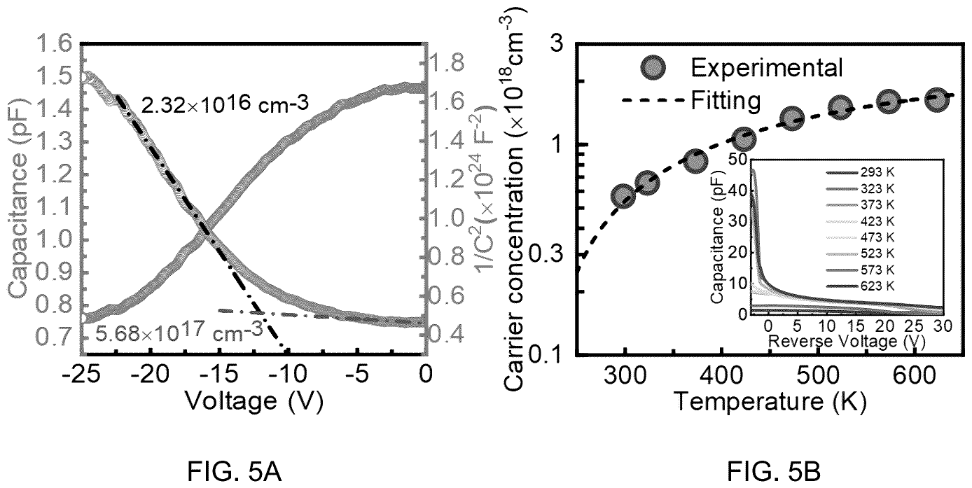

Furthermore, C-V measurements can be used to extract the carrier concentration of the AlN epilayers using the following equations:

$$\frac{1}{\text{?}} = \frac{2}{\text{?}} ( {V}_{bi} - V - kT / q ) \qquad ( 3 )$$

$$d ( \frac{1}{\text{?}} ) / dV = - \frac{\text{?}}{\text{?}} \qquad ( 4 )$$

$$\text{?} \text{indicates text missing or illegible when filed}$$

Where V_{bi} is the built-in voltage, co is the permittivity of the vacuum, and εᵣ is the relative permittivity of AlN (εᵣ=9.2). FIG. 5A shows the C-V and 1/C²-V plots of the device. C-V measurements of the devices were performed at 10 kHz. The 1/C²-V plot had two regions, corresponding to the AlN UID layer and n-doped AlN, respectively. The extracted carrier concentration of the UID layer was 2.3×10¹⁶ cm⁻³, whereas the n-doped region has a carrier concentration of 5.7×10¹⁷ cm⁻³, which is smaller than the Si doping concentration due at least in part to dopant compensation in AlN, which can lead to high Si donor ionization energy in AlN. FIG. 5B shows temperature-dependent carrier concentration can be extracted from temperature-dependent C-V measurements of the devices. As the temperature increases the carrier concentration varied between 5.7×10¹⁷-1.6×10¹⁸ cm⁻³ from 298 K to 623 K. As the temperature increases, more carriers are excited and can contribute to the additional capacitance observed.

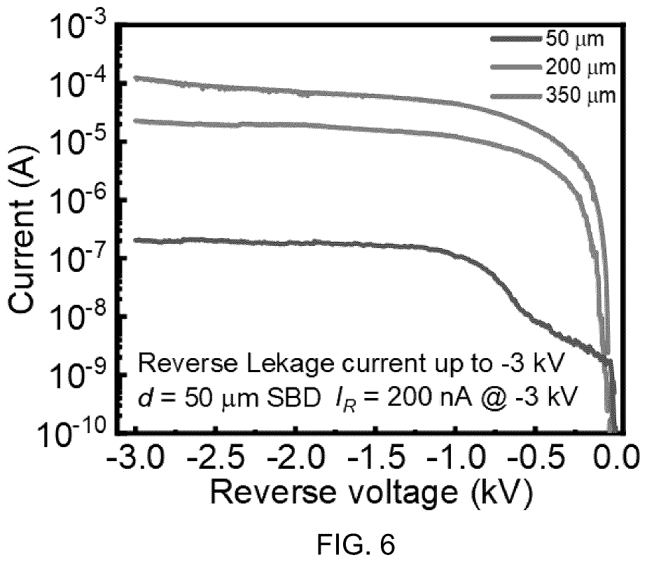

FIG. 6 shows the reverse I-V characteristics of the AlN SBDs with different contact distances up to −3 kV. All the devices exhibited breakdown voltage (BV) of over 3 kV. No destructive breakdown of the devices was observed up to −3 kV. The AlN SBD with a contact distance of 50 μm showed a low reverse leakage of ˜200 nA at −3 kV. The reverse leakage current increased with increasing contact distance, indicating that surface leakage is dominant and increases with the area of the devices.

Although this disclosure contains many specific embodiment details, these should not be construed as limitations on the scope of the subject matter or on the scope of what may be claimed, but rather as descriptions of features that may be specific to particular embodiments. Certain features that are described in this disclosure in the context of separate embodiments can also be implemented, in combination, in a single embodiment. Conversely, various features that are described in the context of a single embodiment can also be implemented in multiple embodiments, separately, or in any suitable sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

Particular embodiments of the subject matter have been described. Other embodiments, alterations, and permutations of the described embodiments are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional), to achieve desirable results.

Accordingly, the previously described example embodiments do not define or constrain this disclosure. Other changes, substitutions, and alterations are also possible without departing from the spirit and scope of this disclosure.

What is claimed is:

1. A Schottky barrier diode comprising:
an AlN substrate;
an AlN layer formed by metalorganic chemical vapor deposition on the AlN substrate;
a Si-doped n-AlN layer formed by metalorganic chemical vapor deposition on the AlN layer;
a GaN capping layer;
an Ohmic contact on the GaN capping layer; and
a Schottky contact on the GaN capping layer,
wherein a breakdown voltage of the Schottky barrier diode exceeds 3 kV.

2. The Schottky barrier diode of claim 1, wherein the AlN substrate comprises (0001) bulk AlN.

3. The Schottky barrier diode of claim 2, wherein the AlN substrate is formed by physical vapor transport.

4. The Schottky barrier diode of claim 1, wherein a thickness of the AlN layer is about 1 μm.

5. The Schottky barrier diode of claim 1, wherein a thickness of the Si-doped n-AlN layer is about 200 nm.

6. The Schottky barrier diode of claim 1, wherein the Si doping concentration in the n-AlN layer is about 1×10¹⁹ cm⁻³.

7. The Schottky barrier diode of claim 1, wherein a thickness of the GaN capping layer is about 2 nm.

8. The Schottky barrier diode of claim 1, wherein the Ohmic contact comprises Ti/Al/Ni/Au.

9. The Schottky barrier diode of claim 1, wherein the Schottky contact comprises Pt/Au.

10. The Schottky barrier diode of claim 1, wherein the Ohmic contact has a cylindrical cross section and surrounds the Schottky contact.

11. The Schottky barrier diode of claim 10, wherein the Schottky contact has a circular cross section.

12. The Schottky barrier diode of claim 11, wherein a distance between an outer diameter of the Schottky contact and an inner diameter of the Ohmic contact is in a range of about 50 μm to about 350 μm.

13. The Schottky barrier diode of claim 1, wherein a thickness of the Ohmic contact and the Schottky contact is about 100 μm.

14. The Schottky barrier diode of claim 1, wherein the diode has an ON/OFF ratio in a range of about 10⁶ to 10⁸.

15. The Schottky barrier diode of claim 1, wherein the diode is thermally stable from 298 K to 623 K.

16. The Schottky barrier diode of claim 1, wherein the Schottky barrier height increases from 0.89 eV to 1.85 eV and the ideality factor decreases from 4.29 to 1.95 with increasing temperature.

17. The Schottky barrier diode of claim 1, wherein, at reverse bias of −3 kV, the diode has a leakage current of 200 nA.

18. The Schottky barrier diode of claim 1, wherein the diode is free of field plate structures.

19. The Schottky barrier diode of claim 1, wherein the diode is free of passivation structures.

20. The Schottky barrier diode of claim 1, wherein the diode is free of edge termination structures.

21. The Schottky barrier diode of claim 1, wherein the AlN layer is unintentionally doped.

22. The Schottky barrier diode of claim 1, wherein the GaN capping layer is unintentionally doped.

23. A method of fabricating a Schottky barrier diode, the method comprising:
depositing a first AlN layer on an AlN substrate, wherein the first AlN layer comprises AlN;
depositing a second AlN layer on the first AlN layer, wherein the second AlN layer comprises silicon-doped AlN;
depositing a capping layer on the second AlN layer, wherein the capping layer comprises GaN;
forming an Ohmic contact on the capping layer via electron beam deposition followed by rapid thermal annealing; and
forming a Schottky contact on the capping layer by electron beam evaporation.
